(19) United States
(12) Patent Application Publication
(10) Pub. No.: US 2021/0057577 A1
(43) Pub. Date: Feb. 25, 2021

(54) Power Semiconductor Module and Method for Fabricating a Power Semiconductor Module

(71) Applicant: Infineon Technologies AG, Neubiberg (DE)

(72) Inventors: Christoph Koch, Salzkotten (DE); Sebastian Klauke, Bestwig (DE); Mark Nils Muenzer, Neubiberg (DE)

(21) Appl. No.: 16/991,326

(22) Filed: Aug. 12, 2020

(30) Foreign Application Priority Data
Aug. 20, 2019 (DE) 102019122369.5

(51) Int. Cl. H01L 29/78; H01L 23/31; G01R 35/00; H01L 29/66; H01L 21/56

(52) U.S. Cl. CPC H01L 29/7815; H01L 23/3157; H01L 21/56; H01L 29/66712; G01R 35/005

(57) ABSTRACT

A power semiconductor module includes a power semiconductor chip, an external contact electrically coupled to the power semiconductor chip, the external contact being configured to carry an alternating current and the external contact comprising an opening, and a current sensor assembly including a current sensor and being at least partially arranged in the opening, wherein the current sensor is configured to measure the alternating current.

### TECHNICAL FIELD

This disclosure relates in general to a power semiconductor module and to a method for fabricating a power semiconductor module.

### BACKGROUND

Power semiconductor modules may be configured to operate with high electrical currents and/or high voltages. Sensors like current sensors may be used to measure the electrical performance of a power semiconductor module and control settings may be adapted based on the measurements. In order to operate a power semiconductor module within narrow performance tolerances, the measurements have to fulfill high precision requirements. Furthermore, mounting of the sensors may contribute significantly to the overall fabrication costs of a power semiconductor module. Improved power semiconductor modules and improved methods for fabricating a power semiconductor module may help to redress these and other problems.

The problem on which the invention is based is solved by the features of the independent claims. Further advantageous examples are described in the dependent claims.

### SUMMARY

Various aspects pertain to a power semiconductor module, comprising: a power semiconductor chip, an external contact electrically coupled to the power semiconductor chip, the external contact being configured to carry an alternating current and the external contact comprising an opening, and a current sensor assembly comprising a current sensor and being at least partially arranged in the opening, wherein the current sensor is configured to measure the alternating current.

Various aspects pertain to a method for fabricating a power semiconductor module, the method comprising: providing a power semiconductor chip and an external contact electrically coupled to the power semiconductor chip, the external contact being configured to carry an alternating current, providing an opening in the external contact, and arranging a current sensor assembly comprising a current sensor at least partially in the opening, wherein the current sensor is configured to measure the alternating current.

### BRIEF DESCRIPTION OF THE DRAWINGS

The accompanying drawings illustrate examples and together with the description serve to explain principles of the disclosure. Other examples and many of the intended advantages of the disclosure will be readily appreciated as they become better understood by reference to the following detailed description. The elements of the drawings are not necessarily to scale relative to each other. Like reference numerals designate corresponding similar parts.

FIGS. 1A and 1B show a side view and a top view of a power semiconductor module which comprises a current sensor assembly.

FIG. 2 shows a side view of a further power semiconductor module that additionally comprises a first carrier and a second carrier.

FIG. 3 shows a perspective view of an external contact and a current sensor assembly that is arranged at least partially within an opening in the external contact.

FIG. 4 shows a perspective detail view of a further power semiconductor module, wherein the current sensor assembly is encapsulated by the first encapsulant.

FIG. 5 shows a perspective detail view of a further power semiconductor module, wherein the current sensor assembly is encapsulated by a second encapsulant, different from the first encapsulant.

FIG. 6 shows a side view of a further power semiconductor module in a stage of fabrication before the second carrier is arranged over the first carrier.

FIG. 7 is a flow chart of a method for fabricating a power semiconductor module.

### DETAILED DESCRIPTION

In the following description the terms “coupled” and “connected”, along with derivatives thereof may be used. It should be understood that these terms may be used to indicate that two elements co-operate or interact with each other regardless whether they are in direct physical or electrical contact, or they are not in direct contact with each other; intervening elements or layers may be provided between the “bonded”, “attached”, or “connected” elements. However, it is also possible that the “bonded”, “attached”, or “connected” elements are in direct contact with each other.

The examples of a power semiconductor module described below may use various types of semiconductor chips or circuits incorporated in the semiconductor chips, among them AC/DC or DC/DC converter circuits, power MOS transistors, power Schottky diodes, JFETs (Junction Gate Field Effect Transistors), power bipolar transistors, logic integrated circuits, analogue integrated circuits, sensor circuits, power integrated circuits, etc. The examples may also use semiconductor chips comprising MOSFET transistor structures or vertical transistor structures like, for example, IGBT (Insulated Gate Bipolar Transistor) structures or, in general, transistor structures in which at least one electrical contact pad is arranged on a first main face of the semiconductor chip and at least one other electrical contact pad is arranged on a second main face of the semiconductor chip opposite to the first main face of the semiconductor chip.

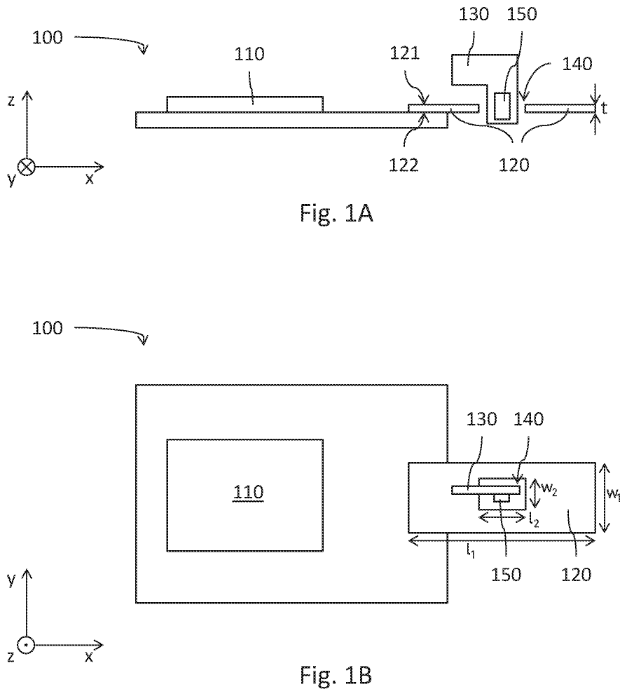

FIG. 1A shows a power semiconductor module 100 that comprises a power semiconductor chip 110, an external contact 120 and a current sensor assembly 130. The external contact 120 is electrically coupled to the power semiconductor chip 110. The external contact 120 is configured to carry an alternating current. The external contact 120 furthermore comprises an opening 140. The current sensor assembly 130 comprises a current sensor 150 that is configured to measure the alternating current and the current sensor assembly is at least partially arranged in the opening 140.

The power semiconductor chip 110 may be configured to operate with high currents and/or high voltages. The power semiconductor chip 110 and/or the external contact 120 may be arranged on a carrier, e.g. a carrier that is configured to operate with high currents and/or high voltages like a direct copper bond (DCB), direct aluminum bond (DAB), active metal brazing (AMB), leadframe etc.

According to an example, the power semiconductor module 100 may comprise more than one semiconductor chips, e.g. more than one power semiconductor chips 110. The more than one semiconductor chips may form a particular electrical circuit, for example a half-bridge circuit, an inverter circuit, etc. A single one of the more than one semiconductor chips or several ones of the more than one semiconductor chips may be electrically coupled to the external contact 120.

The external contact 120 may be configured to provide an electrical connection between the power semiconductor chip 110 and the outside of the power semiconductor module 100. The external contact 120 may e.g. be a power contact that is coupled to a power electrode of the power semiconductor chip 110, e.g. to a source electrode, drain electrode, emitter electrode or collector electrode.

The power semiconductor module 100 may comprise more than one external contact 120. For example, each power electrode of the power semiconductor chip 110 may be coupled to a separate external (power) contact 120. Furthermore, each control electrode (e.g. a gate electrode) of the power semiconductor chip 110 may be coupled to a separate external (control) contact.

According to an example, the power semiconductor module 100 comprises at least a first external contact 120 that is configured to carry a positive supply voltage (V_{DD}), a second external contact 120 that is configured to carry a negative supply voltage (V_{SS}) and a third external contact 120 that is configured as a phase contact. Each of the external contacts 120 may comprise an opening 140 and a current sensor assembly 130 arranged in the respective opening 140. However, it is also possible that only some or only one of the external contacts comprises an opening 140 and a related current sensor assembly 130.

According to an example, the external contact 120 may be coupled to the power semiconductor chip 110 via an electrical connector like a bond wire or a ribbon and/or via the carrier mentioned above. According to an example, the external contact 120 is part of a leadframe.

The external contact 120 may have any suitable dimensions, e.g. a length 11 of 0.5 cm or more, 1 cm or more, 1.5 cm or more or 2 cm or more. The external contact 120 may have a width w₁ of 1 cm or more, 1.4 cm or more or 2 cm or more. The external contact 120 may have a thickness t of 0.8 mm or more, 1 mm or more or 1.2 mm or more.

FIG. 1B shows a top view of the power semiconductor module 100. As shown in FIG. 1B, the opening 140 may have an essentially rectangular outline. However, any other suitable outlines are possible, e.g. a quadratic outline, a circular outline or an elliptical outline.

The opening 140 may be arranged at any suitable position in the external contact 120, e.g. in the center of the external contact 120, at the inner half or at the outer half of it. The opening 140 may have any suitable dimensions l₂, w₂, for example a length l₂ of about 4 mm, about 5 mm, about 6 mm or more than 6 mm and a width w₂ of about 2 mm, about 3 mm, about 4 mm, about 5 mm or more than 5 mm. As shown in FIG. 1A, the opening 140 may extend completely through the external contact 120.

The current sensor assembly 130 comprises the current sensor 150 and it may optionally comprise further active or passive electrical components, for example resistances or capacitances.

According to an example, the current sensor assembly 130 comprises an electrically conductive carrier and the current sensor 150 is arranged on and electrically coupled to the electrically conductive carrier. The electrically conductive carrier e.g. comprises a printed circuit board (PCB).

The current sensor assembly 130 may also comprise one or more electrical contacts that are configured to couple the current sensor assembly 130 to another part of the power semiconductor module 100. For example, the one or more electrical contacts may be configured to couple the current sensor assembly 130 to a logic circuitry or driver circuitry that is configured to control the power semiconductor chip 110. The one or more electrical contacts may be configured to transmit measurement values of the current sensor to the other part of the power semiconductor module 100 (or to an external part) and to provide the current sensor 150 with power.

The current sensor 150 may be any type of sensor that is suitable for measuring a current (in particular, an alternating current) flowing through the external contact 120. The current sensor 150 may e.g. be configured to measure a magnetic field that is caused by the alternating current. For example, the current sensor 150 may comprise one or more magnetic sensor elements like Hall elements or giant magnetoresistive (GMR) elements. It is also possible that the current sensor assembly 130 comprises more than one current sensor 150.

The sensor element(s) (e.g. the magnetic sensor element(s)) may be at least partially arranged in the opening 140. For example, a current sensor 150 may be arranged in the opening 140 such that the current sensor sticks out of a plane defined by the external contact 120 at a first side 121 of the external contact 120 and at a second side 122 opposite the first side 121. The current sensor 150 may for example comprise two or more sensor elements, wherein a first sensor element is arranged at or above the first side 121 and a second sensor element is arranged at or above the second side 122. The sensor element(s) may in particular be arranged such that a specific sensitivity can be achieved.

The current sensor assembly 130 may be arranged in the opening 140 such that no part (in particular, the current sensor 150) of the current sensor assembly 130 touches the external contact 120. The current sensor assembly 130 may be electrically insulated from the external contact 120. According to an example, no further material (e.g. an insulator) may be used to fill the space between the current sensor assembly 130 and the external contact 120. According to another example, an insulator like a polymer is used to fill the space between the current sensor assembly 130 and the external contact 120.

The current sensor 150 may be arranged (essentially) perpendicular with respect to the external contact 120. For example, as shown in FIGS. 1A and 1B, the external contact 120 may be arranged in the xy-plane and the current sensor 150 may be arranged in the xz-plane, perpendicular to the xy-plane.

It is also possible that the whole current sensor assembly 130, most of the current sensor assembly 130 or at least some parts of the current sensor assembly 130 are arranged perpendicular to the external contact 120.

Arranging the current sensor 150 perpendicular to the external contact 120 (and therefore also perpendicular to the alternating current flowing through the external contact 120) may increase the sensitivity of the current sensor 150 compared to other orientations. Furthermore, arranging the current sensor 150 in the opening 140 may also increase the sensitivity of the current sensor 150 compared to arranging the current sensor 150 at other positions relative to the external contact 120.

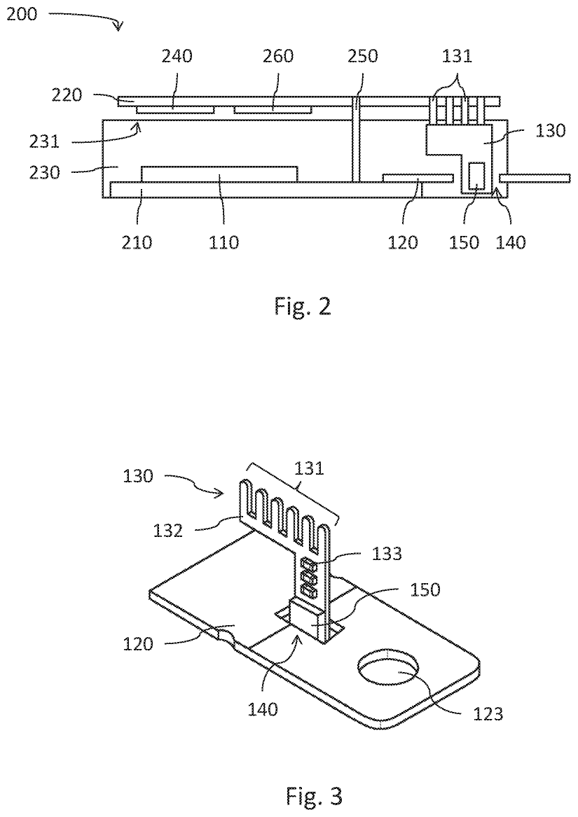

FIG. 2 shows a power semiconductor module 200 which may be similar or identical to the power semiconductor module 100, except for the differences described below.

The power semiconductor module 200 comprises all parts described above with respect to the power semiconductor module 100 and it additionally comprises a first carrier 210 and a second carrier 220. The power semiconductor module 200 may furthermore comprise an encapsulant 230 encapsulating at least the power semiconductor chip 110.

The power semiconductor chip 110 and the external contact 120 may be arranged on and electrically coupled to the first carrier 210. The first carrier 210 may e.g. be a DCB, DAB, AMB, leadframe, a substrate comprising multiple layers of conductive and nonconductive material etc. The second carrier 220 may be arranged such that it faces the first carrier 210. For example, the second carrier 220 may be arranged above the power semiconductor chip 110 and/or the external contact 120.

The second carrier 220 may e.g. be a PCB. The second carrier 220 may comprise logic and/or driver circuitry 240 that is configured to drive the power semiconductor chip 110. The current sensor assembly 130 may be connected to the logic and/or driver circuitry 240. The power semiconductor module 200 may comprise one or more first electrical connectors 250 that couple the first carrier 210 (in particular a control electrode of the power semiconductor chip 110) to the second carrier 220.

The power semiconductor module 200 may further comprise a memory unit 260 that is configured to store calibration parameters of the current sensor assembly 130 and/or electrical performance data of the power semiconductor module 200. The memory unit 260 may e.g. be arranged on the second carrier 220, on the first carrier 210 or on the current sensor assembly 130.

The current sensor assembly 130 may comprise one or more second electrical connector 131 that electrically and possibly also mechanically couple the current sensor assembly 130 to the second carrier 220.

The first electrical connector(s) 250 and/or the second electrical connector(s) may for example form through-hole connections or pressfit connections with the second carrier 220. It is also possible that the current sensor assembly 130 is e.g. soldered onto the second carrier 220.

The encapsulant 230 may at least partially encapsulate the first carrier 210. The external contact 120 may extend out of the encapsulant 230. According to an example, the current sensor assembly 130 is encapsulated by the encapsulant 230. According to another example, the current sensor assembly 130 is arranged outside of the encapsulant 230.

The second carrier 220 may be arranged outside of the encapsulant 230. For example, the second carrier 220 may be arranged at a first surface 231 of the encapsulant 230. The second carrier 220 may be fixed to the encapsulant 230 (in particular, to the first surface 231), e.g. using screws, rivets or glue.

According to an example, the encapsulant 230 may comprise a (hard) plastic frame. The plastic frame may be fixed to the first carrier 210, e.g. using screws, rivets or glue. The encapsulant 230 may further comprise a (hard) plastic lid, wherein the lid is arranged over the plastic frame. The lid may e.g. be fixed to the frame by clamps comprised in the frame or by screws or by pressfit pins. Together, the frame and lid may form a cavity, wherein the power semiconductor chip 110 may be arranged within the cavity. The cavity may at least partially be filled with e.g. a gel that encapsulates the power semiconductor chip 110. The gel may e.g. improve an electrical insulation between electrical connections like bond wires comprised in the cavity. According to an example, the encapsulant 230 may comprise a molded body.

In the case that the current sensor assembly 130 is encapsulated by the encapsulant 230 and the second carrier is arranged outside the encapsulant 230, the second electrical connectors 131 may extend through the encapsulant 230 (as shown in FIG. 2). The encapsulant 230 may comprise dedicated through-holes for the second electrical connectors 131.

FIG. 3 shows a perspective detail view of the external contact 120 and the current sensor assembly 130 arranged at least partially within the opening 140.

According to an example, the current sensor assembly 130 comprises a carrier 132, wherein the current sensor 150 is mechanically and electrically coupled to the carrier 132. The current sensor assembly 130 may further comprise additional active or passive electrical components 133. The additional electrical components 133 may be arranged laterally besides the current sensor 150 on the carrier 132.

A connector part of the carrier 132 comprising the second electrical connectors 131 may have a larger extension along the x-axis than a sensor part comprising the current sensor 150 and being arranged within the opening 140. The connector part may also have a larger extension along the x-axis than the opening 140 (compare also FIGS. 1A and 1B).

The larger extension of the connector part along the x-axis may provide sufficient space for the second electrical connectors 131, whereas the smaller extension of the sensor part along the x-axis may allow for comfortably positioning of the sensor part within the opening 140.

As shown in FIG. 3, the external contact 120 may comprise a further opening 123 which may be arranged laterally besides the opening 140. The further opening 123 may e.g. be configured to fix the external contact to another element. The further opening 123 may e.g. be located on a part of the external contact 120 that is arranged outside the encapsulant 230.

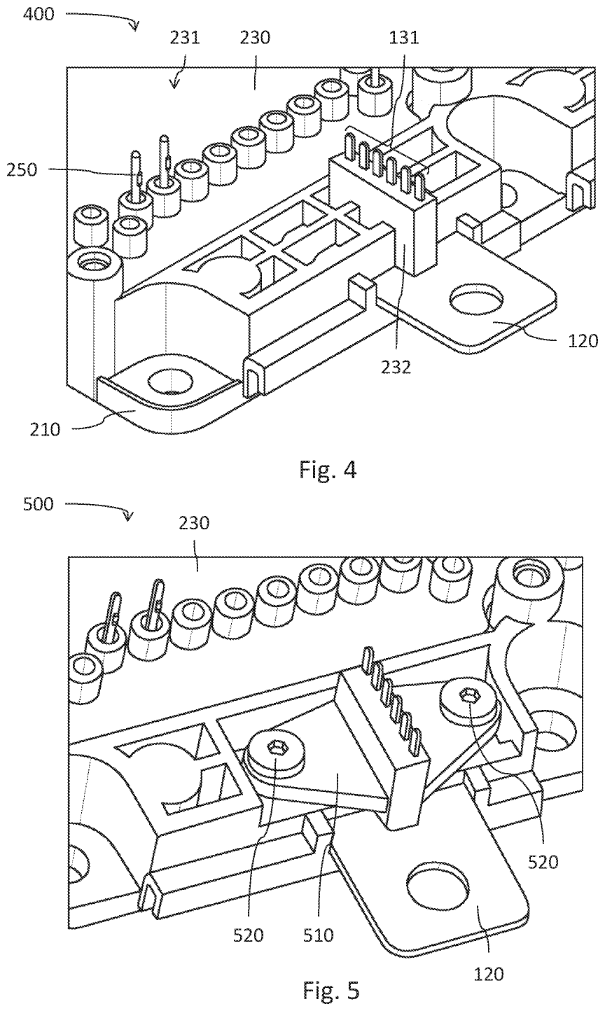

FIG. 4 shows a perspective detail view of a power semiconductor module 400 which may be similar or identical to the power semiconductor modules 100 and 200.

In the power semiconductor module 400 the current sensor assembly 130 is arranged within the encapsulant 230. To this end, the encapsulant 230 may comprise a dedicated cavity 232 that is configured to receive the current sensor assembly 130. The second electrical connectors 131 may extend to the outside from a surface of the cavity 232. The cavity 232 may be an integral part of the encapsulant 230.

According to an example, the current sensor assembly 130 may be arranged within the cavity 232 prior to arranging the encapsulant 230 over the first carrier 210 and thereby arranging the current sensor assembly in the opening 140. According to another example, the current sensor assembly 130 may be arranged in the opening 140 prior to arranging the encapsulant 230 over the first carrier 210 the current sensor assembly 130. According to yet another example, the current sensor assembly 130 may be inserted into the cavity 232 after the encapsulant 230 has been arranged over the first carrier 210.

The encapsulant 230 may further comprise through-holes that are configured to accept the first electrical connectors 250.

FIG. 5 shows a perspective detail view of a further power semiconductor module 500 which may be similar or identical to the power semiconductor modules 100, 200 and 400, except for the differences described in the following.

In the power semiconductor module 500 the current sensor assembly 130 is not arranged within the encapsulant 230. In other words, the encapsulant 230 does not encapsulate the current sensor assembly 130. Instead, the power semiconductor module 500 comprises a further (second) encapsulant 510 apart from the (first) encapsulant 230.

The current sensor assembly 130 is encapsulated by the second encapsulant 510. The second encapsulant 510 may comprise through-holes or slits for the second electrical connectors 131 to extend to the outside.

According to an example, the second encapsulant 510 comprises a (hard) plastic frame. The current sensor assembly 130 may e.g. be inserted into the plastic frame. According to another example, the second encapsulant 510 comprises a molded body that may be molded over the current sensor assembly 130 in a molding tool.

The second encapsulant 510 may be fixed onto the first encapsulant 230 or onto the first carrier 210. For example, the second encapsulant 510 may be fixed onto the first encapsulant 230 using one or more screws 520. Alternatively, other fixing means like rivets or glue may be used.

The second encapsulant 510 may be fixed onto the first encapsulant 230 after the first encapsulant 230 has been arranged over the power semiconductor chip 110 and the first carrier 210. Alternatively, the second encapsulant 510 may be fixed onto the first encapsulant 230 before the first encapsulant 230 is arranged over the power semiconductor chip 110 and the first carrier 210. The current sensor assembly 130 may be encapsulated by the second encapsulant 510 prior to fixing the second encapsulant 510 onto the first encapsulant 230.

The second carrier 220 (compare FIG. 2) may be arranged over the first encapsulant 230 and the second encapsulant 510 after the second encapsulant 510 has been arranged on the first encapsulant 230.

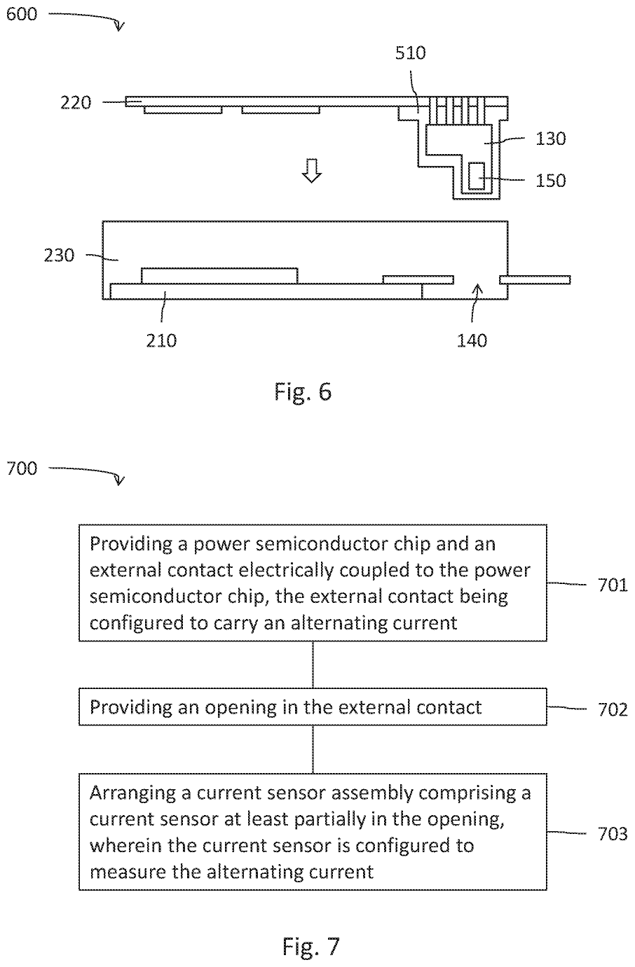

FIG. 6 shows a further power semiconductor module 600 in a stage of fabrication. The power semiconductor module 600 may be similar or identical to the power semiconductor modules 100, 200, 400 and 500, except for the differences described below.

In the power semiconductor module 600 the current sensor assembly 130 is fixed onto the second carrier 220 prior to arranging the second carrier 220 over the first carrier 210. The current sensor module 130 is inserted into the opening 140 when the second carrier 220 is arranged over the first carrier 210.

According to an example, the current sensor assembly 130 is encapsulated by the second encapsulant 510. The second encapsulant 510 may be fixed onto the second carrier 220. According to another example, the current sensor assembly 130 is not encapsulated by the second encapsulant 510. Instead, the current sensor assembly 130 is inserted into the cavity 232 of the first encapsulant 230 (compare FIG. 4) when the second carrier 220 is arranged over the first carrier 210.

The power semiconductor module 600 may comprise more than one current sensor modules 130 and the more than one current sensor modules 130 may be mechanically linked by a support structure, e.g. before the more than one current sensor modules 130 are fixed onto the second carrier 220 or after they have been fixed onto the second carrier 220.

FIG. 7 is a flow chart of a method 700 for fabricating a power semiconductor module. The method 700 may e.g. be used to fabricate the power semiconductor modules 100, 200, 400, 500 and 600.

The method 700 comprises at 701 providing a power semiconductor chip and an external contact electrically coupled to the power semiconductor chip, the external contact being configured to carry an alternating current, at 702 providing an opening in the external contact, and at 703 arranging a current sensor assembly comprising a current sensor at least partially in the opening, wherein the current sensor is configured to measure the alternating current.

The method 700 may optionally comprise encapsulating the power semiconductor chip and/or the current sensor assembly with an encapsulant. The method 700 may further comprise arranging driver circuitry above the power semiconductor chip and the external contact, wherein the driver circuitry is configured to drive the power semiconductor chip and wherein the current sensor assembly is arranged in the opening prior to arranging the driver circuitry above the power semiconductor chip and the external contact. Alternatively, the method 700 may comprise arranging a carrier comprising driver circuitry above the power semiconductor chip and the external contact, wherein the driver circuitry is configured to drive the power semiconductor chip and wherein the current sensor assembly is mounted on the carrier prior to arranging the carrier above the power semiconductor chip and the external contact.

According to an example, the power semiconductor chip is encapsulated in a first encapsulant, the current sensor assembly is encapsulated in a second encapsulant and the second encapsulant is mounted onto the first encapsulant using a screw, a rivet or glue.

According to another example of the method 700, calibration parameters of the current sensor assembly are obtained and stored in a memory unit of the power semiconductor module.

### Examples

In the following, the power semiconductor module and the method for fabricating a power semiconductor module are further described using specific examples.

Example 1 is a power semiconductor module, comprising: a power semiconductor chip, an external contact electrically coupled to the power semiconductor chip, the external contact being configured to carry an alternating current and the external contact comprising an opening, and a current sensor assembly comprising a current sensor and being at least partially arranged in the opening, wherein the current sensor is configured to measure the alternating current.

Example 2 is the power semiconductor module of example 1, wherein the current sensor assembly is arranged essentially perpendicular to the external contact.

Example 3 is the power semiconductor module of example 1 or 2, wherein the external contact is arranged in a plane and wherein the current sensor assembly comprises at least two sensor elements that are arranged above and below the plane, respectively.

Example 4 is the power semiconductor module of one of the preceding examples, further comprising: a first carrier, wherein the power semiconductor chip and the external contact are arranged on the first carrier, and a second carrier comprising driver circuitry, the driver circuitry being configured to drive the power semiconductor chip, wherein the current sensor assembly is essentially arranged between the first carrier and the second carrier.

Example 5 is the power semiconductor module of example 4, wherein the current sensor assembly is coupled to the second carrier by a solder joint or a pressfit connection.

Example 6 is the power semiconductor module of example 4 or 5, wherein the current sensor assembly comprises an electrically conductive carrier carrying the current sensor and at least one passive electrical component.

Example 7 is the power semiconductor module of one of the preceding examples, further comprising: a first carrier, wherein the power semiconductor chip is mounted on the first carrier, and an encapsulant encapsulating at least part of the first carrier and the current sensor assembly.

Example 8 is the power semiconductor module of one of claims 1 to 6, further comprising: a first carrier, wherein the power semiconductor chip is mounted on the first carrier, and a first encapsulant encapsulating at least part of the first carrier, and a second encapsulant encapsulating the current sensor assembly.

Example 9 is the power semiconductor module of example 8, wherein the second encapsulant is mounted on the first encapsulant using a screw, a rivet or glue.

Example 10 is the power semiconductor module of one of the preceding claims, further comprising: a memory unit configured to store calibration parameters of the current sensor assembly and/or electrical performance data of the power semiconductor module.

Example 11 is a method for fabricating a power semiconductor module, the method comprising: providing a power semiconductor chip and an external contact electrically coupled to the power semiconductor chip, the external contact being configured to carry an alternating current, providing an opening in the external contact, and arranging a current sensor assembly comprising a current sensor at least partially in the opening, wherein the current sensor is configured to measure the alternating current.

Example 12 is the method of example 11, further comprising: encapsulating the current sensor assembly with an encapsulant.

Example 13 is the method of example 12, further comprising: arranging driver circuitry above the power semiconductor chip and the external contact, the driver circuitry being configured to drive the power semiconductor chip, wherein the current sensor assembly is arranged in the opening prior to arranging the driver circuitry above the power semiconductor chip and the external contact.

Example 14 is the method of example 12, further comprising: arranging a carrier comprising driver circuitry above the power semiconductor chip and the external contact, the driver circuitry being configured to drive the power semiconductor chip, wherein the current sensor assembly is mounted on the carrier prior to arranging the carrier above the power semiconductor chip and the external contact.

Example 15 is the method of example 12 or 13, further comprising: mounting the power semiconductor chip on a first carrier, wherein at least part of the first carrier is encapsulated by a first encapsulant, the current sensor assembly is encapsulated by a second encapsulant and the second encapsulant is mounted on the first encapsulant using a screw, a rivet or glue.

Example 16 is the method of one of examples 11 to 15, further comprising: obtaining calibration parameters of the current sensor assembly and storing the calibration parameters in a memory unit of the power semiconductor module.

While the disclosure has been illustrated and described with respect to one or more implementations, alterations and/or modifications may be made to the illustrated examples without departing from the spirit and scope of the appended claims. In particular regard to the various functions performed by the above described components or structures (assemblies, devices, circuits, systems, etc.), the terms (including a reference to a “means”) used to describe such components are intended to correspond, unless otherwise indicated, to any component or structure which performs the specified function of the described component (e.g., that is functionally equivalent), even though not structurally equivalent to the disclosed structure which performs the function in the herein illustrated exemplary implementations of the disclosure.

What is claimed is:

1. A power semiconductor module, comprising:
a power semiconductor chip;
an external contact electrically coupled to the power semiconductor chip, the external contact being configured to carry an alternating current and the external contact comprising an opening; and
a current sensor assembly comprising a current sensor and being at least partially arranged in the opening, the current sensor being configured to measure the alternating current.

2. The power semiconductor module of claim 1, wherein the current sensor assembly is arranged perpendicular to the external contact.

3. The power semiconductor module of claim 1, wherein the external contact is arranged in a plane, and wherein the current sensor assembly comprises at least two sensor elements that are arranged above and below the plane, respectively.

4. The power semiconductor module of claim 1, further comprising:
a first carrier; and
a second carrier comprising driver circuitry, the driver circuitry being configured to drive the power semiconductor chip,
wherein the power semiconductor chip and the external contact are arranged on the first carrier,
wherein the current sensor assembly is arranged between the first carrier and the second carrier.

5. The power semiconductor module of claim 4, wherein the current sensor assembly is coupled to the second carrier by a solder joint or a pressfit connection.

6. The power semiconductor module of claim 4, wherein the current sensor assembly comprises an electrically conductive carrier carrying the current sensor and at least one passive electrical component.

7. The power semiconductor module of claim 1, further comprising:
a first carrier on which the power semiconductor chip is mounted; and
an encapsulant encapsulating at least part of the first carrier and the current sensor assembly.

8. The power semiconductor module of claim 1, further comprising:
a first carrier on which the power semiconductor chip is mounted;
a first encapsulant encapsulating at least part of the first carrier; and
a second encapsulant encapsulating the current sensor assembly.

9. The power semiconductor module of claim 8, wherein the second encapsulant is mounted on the first encapsulant using a screw, a rivet or glue.

10. The power semiconductor module of claim 1, further comprising:
a memory unit configured to store calibration parameters of the current sensor assembly and/or electrical performance data of the power semiconductor module.

11. A method for fabricating a power semiconductor module, the method comprising:
providing a power semiconductor chip and an external contact electrically coupled to the power semiconductor chip, the external contact being configured to carry an alternating current;
providing an opening in the external contact; and
arranging a current sensor assembly comprising a current sensor at least partially in the opening, the current sensor being configured to measure the alternating current.

12. The method of claim 11, further comprising:
encapsulating the current sensor assembly with an encapsulant.

13. The method of claim 12, further comprising:
arranging driver circuitry above the power semiconductor chip and the external contact, the driver circuitry being configured to drive the power semiconductor chip,
wherein the current sensor assembly is arranged in the opening prior to arranging the driver circuitry above the power semiconductor chip and the external contact.

14. The method of claim 12, further comprising:
arranging a carrier comprising driver circuitry above the power semiconductor chip and the external contact, the driver circuitry being configured to drive the power semiconductor chip,
wherein the current sensor assembly is mounted on the carrier prior to arranging the carrier above the power semiconductor chip and the external contact.

15. The method of claim 12, further comprising:
mounting the power semiconductor chip on a first carrier,
wherein at least part of the first carrier is encapsulated by a first encapsulant,
wherein the current sensor assembly is encapsulated by a second encapsulant,
wherein the second encapsulant is mounted on the first encapsulant using a screw, a rivet or glue.

16. The method of claim 11, further comprising:
obtaining calibration parameters of the current sensor assembly; and
storing the calibration parameters in a memory unit of the power semiconductor module.
